(19) United States
(12) Patent Application Publication
(10) Pub. No.: US 2021/0247581 A1
(43) Pub. Date: Aug. 12, 2021

(54) Optical Distribution Chassis and Cassette

(71) Applicant: Codecom Pty Ltd, Victoria (AU)

(72) Inventor: Cade Lever, Victoria (AU)

(21) Appl. No.: 16/324,593

(22) PCT Filed: Aug. 7, 2018
(86) PCT No.: PCT/IB2018/055925

§ 371 Date: Feb. 11, 2019

(51) Int. Cl. G02B 6/44

(52) U.S. Cl. CPC G02B 6/4452; G02B 6/4446; G02B 6/4455

(57) ABSTRACT

The invention discloses an optical distribution chassis (100) and cassette (200). The chassis comprises an intermediate horizontal wall (107) dividing the enclosure into an upper enclosure and a lower enclosure, where the upper enclosure is configured for receiving the cassettes (200) and the lower enclosure is configured for introduction and organization of cables. The cassettes (200) are secured inside the chassis (100) by means of slots (108) in the chassis for slidably receiving respective mating rails (207) in each cassette (200). Locking recesses (109) located adjacent a front end of each slot (108) receive respective mating locking protrusions (208) provided in each cassette (200) for firmly securing the cassettes (200) inside the chassis (100).

### OBJECT OF THE INVENTION A first object of the present invention is an optical distribution chassis designed for housing a plurality of cassettes releasably locked therein.

A second object of the present invention is an optical distribution cassette particularly designed for being releasably locked into the aforementioned optical distribution chassis.

A third object of the present invention is a system comprising an optical distribution chassis and a plurality of optical distribution cassettes releasabley lockable therein.

### BACKGROUND ART

Optical distribution chassis for fiber termination and cross connect applications are known in the art. Said chassis are intended for receiving a plurality of cables for connection or splicing purposes.

The large number of cables pose an important drawback, since the space inside the cabinets is limited, and therefore so is the space inside the chassis.

### DESCRIPTION OF THE INVENTION

The present invention solves the aforementioned drawbacks by means of a chassis and cassette having a new and improved design. The chassis comprises a number of cassette-receiving slots strategically located for avoiding crossings between incoming and outgoing cables. In particular, the chassis does not include any moving parts, in the sense that the slots are so located that the user needs not displace the cassettes in order to access the cables. The cassettes are releasably lockable into the chassis in a simple and reliable manner.

The following terms are used throughout the present specification. These terms are further disclosed in the present document in connection with the attached drawings:
Depth-wise direction: A horizontal direction between the front and the back of the chassis or cassette.
Height-wise direction: A vertical direction between the bottom and the top of the chassis or cassette.
Width-wise direction: A horizontal direction between the left-hand side and the right-hand side of the chassis or cassette.
Rack unit (U): U is a unit of measure defined as 44.50 millimeters (1.75 inches) and usually employed in connection to the height of rack frames and the equipment mounting these frames.

Chassis

A first aspect of the invention is directed to a chassis designed for housing a plurality of optical distribution cassettes in a side-by-side fashion. The chassis comprises an essentially parallelepipedic enclosure limited by an upper wall, a bottom wall, lateral walls, a back wall, and a front door. In a non-limiting preferred embodiment, each wall may be formed by one or more individual parts, these parts being assembled to form the enclosure, as more clearly disclosed below in connection with the drawings. The chassis further comprises coupling means for coupling said chassis inside a networking cabinet. The coupling means are preferably strategically located holes intended for receiving respective screws.

The chassis of the invention further comprises the following novel features:

a) An intermediate horizontal wall dividing the enclosure into an upper enclosure and a lower enclosure, where the depth of the intermediate horizontal wall is smaller than the depth of the enclosure. Thus, there is a passage connecting the upper enclosure and the lower enclosure adjacent the front door when closed.
The division of the enclosure into an upper enclosure and the lower enclosure is advantageous in that the lower enclosure is used for the introduction and layout of cables and the upper enclosure is used for housing the plurality of cassettes. The lower enclosure provides plenty of space for the cables to be well organized, the cables passing through the passage communicating with the upper enclosure for connection to the respective cassettes.

In a particularly preferred embodiment of the chassis, the front side of the intermediate horizontal wall and the front side of the upper wall each comprise a plurality of fingers separated by respective gaps for the passage of cables, each gap being essentially aligned with one of the plurality of slots for receiving the cassettes. The user can therefore pass a bundle of cables from the lower enclosure to the upper enclosure, or from the outside to the upper enclosure, through a corresponding gap for connection to a particular cassette. This feature allows for a more structured and clear organization of the cabling inside the chassis.

b) An upper surface of the intermediate horizontal wall and a lower surface of the upper wall each comprise:
A plurality of slots oriented in a depth-wise direction for slidably receiving respective mating rails provided in each cassette.
A plurality of locking recesses each located adjacent a front end of each slot for receiving respective mating locking protrusions provided in each cassette.

This configuration is intended for releasably securing a plurality of cassettes in the upper enclosure of the chassis. To this purpose, the opposing intermediate and upper walls limiting the upper enclosure have respective depth-wise slots configured for receiving respective upper and lower rails of each cassette. The user can therefore push a cassette along the desired slot until a locking protrusion of the cassette enters a locking recess, whereupon the cassette is secured to the chassis. The cassette can be released by pushing a tongue provided in the cassette in order for the locking protrusion to exit the locking recess. The cassette can then be pulled out from the chassis.

This configuration is advantageous in that the cassettes can be secured into the chassis and extracted therefrom in a simple, fast and reliable manner.

c) The lower enclosure comprises front lateral openings and back openings for the passage of outgoing cables from the cassettes, and the upper enclosure comprises front lateral openings and back openings for the passage of incoming cables to the cassettes.

Usually, incoming cables enter the chassis from above and outgoing cables enter the chassis from below. The provision of several openings to both the upper and the lower enclosure is advantageous in that they provide for a number of different possibilities for cable layout depending on the circumstances of each case.

In a particular preferred embodiment of the chassis, the front lateral openings of the lower enclosure are openings in a front bottom section of the lateral walls adjacent the front side of the lower enclosure. Cables entering the front lateral openings of the lower enclosure are then channeled through the corresponding gaps between the fingers of the intermediate wall towards the cassettes.

In another preferred embodiment, the chassis further comprises an additional vertical wall separating a front side of the lower enclosure from a back side of the lower enclosure. In this case, the back openings of the lower enclosure are preferably openings in said additional vertical wall. These back openings allow for the cables to enter the lower enclosure of the chassis from behind.

In a still further preferred embodiment of the chassis, the front lateral openings of the upper enclosure are openings in a front upper section of the lateral walls. Cables entering the upper enclosure can then be channeled through the gaps between corresponding fingers before connection with the cassettes.

In a further preferred embodiment of the chassis, the back openings of the upper enclosure are openings in a back section of the upper wall. Openings in the upper enclosure are usually smaller than those in the lower enclosure, since the number of outgoing cables is usually greater than the number of incoming cables in the relevant applications.

In another preferred embodiment of the chassis, the upper wall comprises a front section and a back section. The back section is vertically displaced downwards with respect to the front section for generating an uppermost volume within the upper enclosure which is intended for upper cable management. The back openings of the upper enclosure are openings in a vertical section of the upper wall connecting the front section and the back section of said upper wall.

The total height of this chassis is preferably 6 U. More preferably, the height of the upper enclosure is 4 U, the height of the uppermost volume within the upper enclosure is 0.5 U, and the height of the lower enclosure is 1.5 U.

In a still further preferred embodiment of the invention, at least one of the front lateral and back openings of the lower enclosure and the front lateral and back openings of the upper enclosure have curved edges for preventing cable damage.

Cassette

A second aspect of the invention is directed to an optical distribution cassette for housing a plurality of optical connections. The cassette comprises an essentially parallelepipedic box having front panel, a back panel, lateral panels, an upper panel and a bottom panel. In a non-limiting preferred embodiment, the panels are embodied in just two parts, as more clearly disclosed below in connection with the drawings. The front panel comprises a plurality of holes for receiving several connectors. The width of the cassette is substantially smaller than the height and depth, such that a plurality of cassettes can be locked side-by-side inside a chassis.

Further, an upper surface of the upper panel and a bottom surface of the bottom panel of the cassette each comprise:
A mating rail oriented in the depth-wise direction for slidably entering respective slots provided in the chassis.
A locking protrusion located adjacent a front end of each rail for entering mating locking recesses provided in the chassis.

This configuration is complementary with respect to the slots and locking recess of the chassis. Thus, the cassette can be inserted in the chassis by causing it to slide depth-wise along the rails of the chassis. The introduction of the locking protrusion of the cassette into the mating locking recess of the chassis secures the cassette in position.

Preferably, each locking protrusion is located at a resilient tongue extending out of a front panel of the cassette. Further, the locking protrusion is preferably wedge shaped. Therefore:
Full introduction of the cassette in the chassis, with the rails provided at the upper panel and bottom panel of the cassette inside the corresponding mating slots provided at the intermediate horizontal wall and the upper wall of the chassis, causes the locking protrusion to enter the locking recess.
Deflection of the tongue upon application of pressure thereon causes the locking protrusion to exit the locking recess in the chassis for extracting the cassette from the chassis.

In a still further preferred embodiment of the invention, the front panel comprises a hole having a pair of slots for receiving a interchangeable plates having differently shaped openings for different types of connectors.

In still one more preferred embodiment of the invention, an inner surface of one of the lateral panels further comprises connection protrusions for the attachment of a splice holder within the cassette.

In a still another preferred embodiment of the present invention, the cassette has a height of 4 U.

Chassis-Cassette System

A third aspect of the invention is directed to an optical distribution system comprising an optical distribution chassis as disclosed above and a plurality of optical distribution cassettes as disclosed above.

### BRIEF DESCRIPTION OF THE DRAWINGS

FIG. 1 shows a perspective view of the chassis of the invention.

FIG. 2 shows a perspective view of a part embodying the slots and locking recess of the chassis of the invention.

FIG. 3 shows a perspective view of a part embodying the fingers and gaps of the chassis of the invention.

FIG. 4 shows a perspective view of a part embodying the lateral walls of the chassis of the invention.

FIG. 5 shows a perspective view of a part embodying the additional vertical wall of the chassis of the invention.

FIG. 6 shows a perspective view of a part embodying the upper wall of the chassis of the invention.

FIGS. 7a and 7b show perspective views of two embodiments of a cassette according to the invention.

FIG. 8 shows a perspective view of a part embodying the upper, lower, front, and back walls and one lateral wall of the cassette of the invention.

FIGS. 9a and 9b show perspective views of two interchangeable plates of the cassette of the invention.

FIG. 10 shows the part of FIG. 8 with two splice holders attached within the cassette.

FIG. 11 shows a perspective view of a chassis of the invention having cassettes housed therein.

FIG. 12 shows a perspective view of a chassis of the invention having cassettes housed therein.

FIG. 13 shows a perspective view of two chassis according to the present invention provided inside a cabinet.

### PREFERRED EMBODIMENT OF THE INVENTION

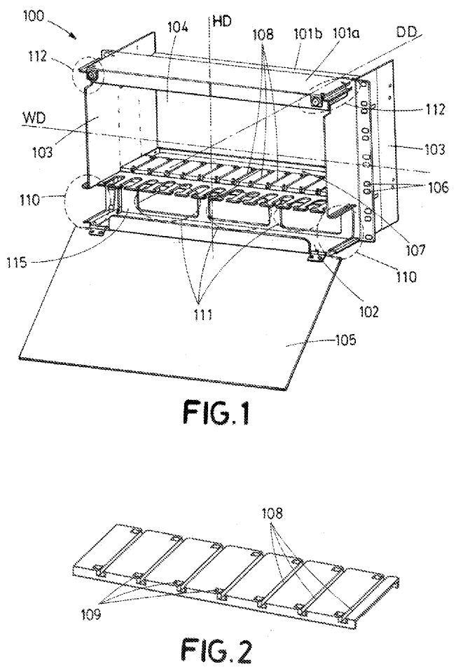

FIG. 1 shows a particular example of an optical distribution chassis (100) according to the invention. The width-wise direction (WD), the height-wise direction (HD) and the depth-wise direction (DD) are shown in FIG. 1.

The chassis (100) is formed as a parallelepipedic box comprising an upper wall (101), a bottom wall (102), lateral walls (103), a back wall (104) and a front door (105) hinged to the front side of the bottom wall (102). In the present example, each wall is formed by an individual plate. The plates are assembled using connection means such as screws or the like for making up the chassis (100). However, this should not be construed as a limitation, as it would be possible for more than one wall to be formed in a single part, or for a wall to be formed by more than one part. The chassis (100) further comprises a vertical lateral plate having a coupling means (106), in the present example a plurality of holes, for coupling the chassis (100) inside a networking cabinet.

The inner enclosure of the chassis (100) is divided by means of an intermediate horizontal wall (107) in two portions: an upper enclosure and a lower enclosure. The upper enclosure is intended for housing the plurality of cassettes (200), while the lower enclosure is intended for providing space for laying out the cables. The depth-wise dimension of the intermediate horizontal wall (107) is smaller than the total depth of the chassis (100), and therefore a passage located adjacent the front side of the chassis (100) allows for the cables to pass between the lower enclosure and the upper enclosure.

The upper wall (101) is formed by a front horizontal section (101a) and a back horizontal section (101b) connected by means of a back vertical section (101c). Thus, an uppermost volume is created at the top of the upper enclosure for managing cables going out from the top section of said uppermost volume towards the back of the chassis (100). Said cables exit the chassis (100) through a number of openings (113) provided in the vertical section (101c) of the upper wall (101).

The upper surface of the intermediate horizontal wall (107) comprises a plurality of parallel slots (108) oriented in a depth-wise direction and a corresponding plurality of locking recesses (109) each located adjacent a front end of a respective slot (108). FIG. 2 shows a plate intended for connection to the upper surface of the rest of the intermediate horizontal wall (107) and having the slots (108) and locking recesses (109) thereon. A similarly configured plate comprising a plurality of slots (108) and locking recesses (109) is also connected to the lower surface of the upper wall (101). In the present example, the locking recesses (109) have a parallelepipedic shape mating a wedge shape of the locking protrusion (208) provided in the cassette (200), and the slots (108) have a straight shape mating corresponding locking rails (207) provided in the cassettes (200).

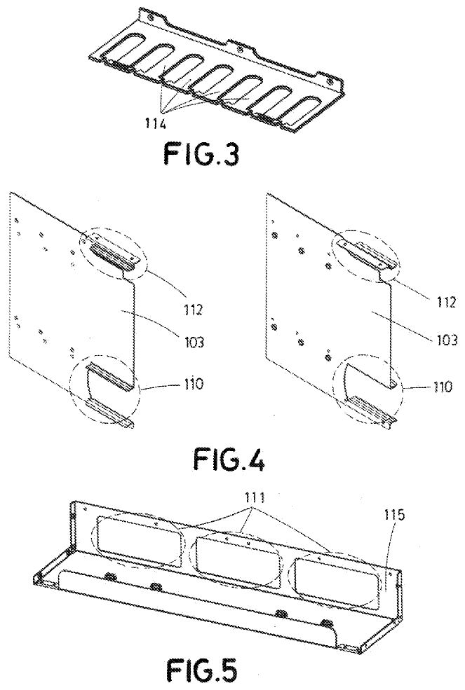

The front side of the intermediate horizontal wall (107) further comprises a plurality of fingers (114) separated by respective gaps. FIG. 3 shows a plate intended for connection to a front side of the rest of the intermediate horizontal wall (107). Therefore, in the present example the intermediate horizontal wall (107) is formed by three interconnected parts: the wall itself, a plate containing the slots (108) and recesses (109), and a plate containing the fingers (114). The gaps are vertically aligned with each of the pairs of slots (108) respectively provided in the intermediate horizontal wall (107) and the top wall (101). Thus, each gap may accommodate cables running from the lower enclosure to a cassette (200) locked to a particular pair of slots (108).

The chassis (100) of the invention further comprises a plurality of openings for the passage of cables. In particular, the front side of each lateral wall (103) comprises a front lower opening (110) and an front upper opening (112). These openings are more clearly shown in FIG. 4, where the respective right-side and left-side lateral walls (103) are shown. Note that the plate forming the lateral walls (103) comprises respective curve edges at each of the openings (110, 112). The curved edges prevent cable damage such as cuts and scratches. The lower opening (110) allows for cables to enter the lower enclosure from the front of the chassis (100), while the upper opening (112) allows for cables to enter the upper enclosure from the front of the chassis (100). Usually, the lower openings (110) are larger than the upper openings (112).

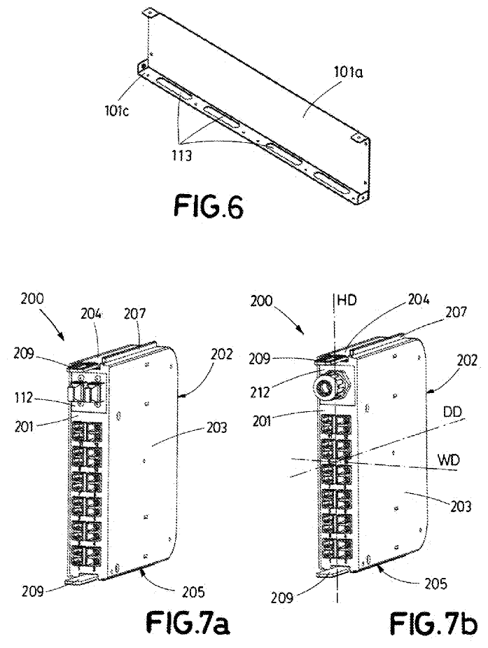

The chassis (100) additionally comprises lower enclosure and upper enclosure back openings (113, 111). The lower enclosure back openings (111) are provided in an additional vertical wall (115) separating a front side of the lower enclosure from a back side of the lower enclosure. The additional vertical wall (115) is shown in detail in FIG. 5. In the present example, the additional vertical wall (115) is a plate having an L-shape cross-section and connected to the bottom wall (102) by means of screws or the like. Three back openings (111) are provided for allowing cables to enter the lower enclosure from behind the chassis (100). The upper enclosure back openings (113) are provided in the upper wall (101), which is also configured as an L-shaped cross-section plate, as shown in FIG. 6. The upper enclosure back openings (113) are usually smaller than the lower enclosure back openings (111).

FIGS. 7a and 7b show two embodiments of a cassette (200) according to the invention. Each cassette (200) is formed as a parallelepipedic box formed by a front panel (201), a back panel (202), lateral panels (203), an upper panel (204) and a bottom panel (205). The front panel (201) comprises a plurality of openings (206) for receiving respective connectors. The width of the cassette (200) is substantially smaller than the height and depth, such that a plurality of cassettes (200) to be locked inside a chassis (100) as disclosed above.

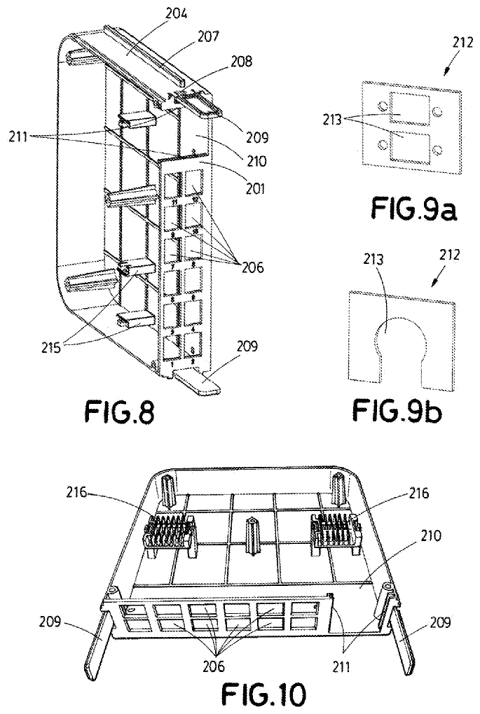

The upper and bottom panels (204, 205) of the cassette each comprise a depth-wise oriented mating rail (207) intended for slidably entering the respective slots (108) of the chassis (100) disclosed above. The rails (207) are configured as straight depth-oriented ribs. A wedge shaped locking protrusion (208) is also provided adjacent the front end of each mating rail (207). Each locking protrusion (208) is located at a resilient tongue (209) extending out of the front panel (201) of the cassette (200). FIG. 8 shows a part comprising the upper and bottom panels (204, 205) of the cassette (200) where the mating rails (207), the locking protrusion (208), and the tongue (209) are shown.

Therefore, when the cassette (200) is completely introduced into the chassis (100), with the rails (207) provided at the upper panel (204) and bottom panel (205) of the cassette (200) inside the corresponding mating slots (108) provided at the intermediate horizontal wall (107) and the upper wall (101) of the chassis (100), the locking protrusion (208) enters the locking recess (109). The cassette (200) is then securely locked inside the chassis (100). The cassette (200) is extracted by deflecting the tongue (209) for causing the locking protrusion (208) to exit the locking recess (109) in the chassis (100). Once the locking protrusion (208) is out of the locking recess (109), the cassette (200) can be pulled out of the chassis (100).

FIG. 8 also shows the front panel (201) of the cassette (200) having a rectangular hole (210) having a pair of width-wise oriented slots (211). Hole (210) is intended for receiving interchangeable plates (212) having differently shaped openings (213) for different types of connectors. FIGS. 9a and 9b show two examples of interchangeable plates (212).

FIG. 8 also shows the inner surface of the lateral panel (203) having two pairs of connection protrusions (215) intended for the attachment of respective splice holders (216). FIG. 10 shows the same part making up the front panel (201), a back panel (202), one of the lateral panels (203), an upper panel (204) and a bottom panel (205) as FIG. 8 with the splice holders (216) attached to the respective connection protrusions (215).

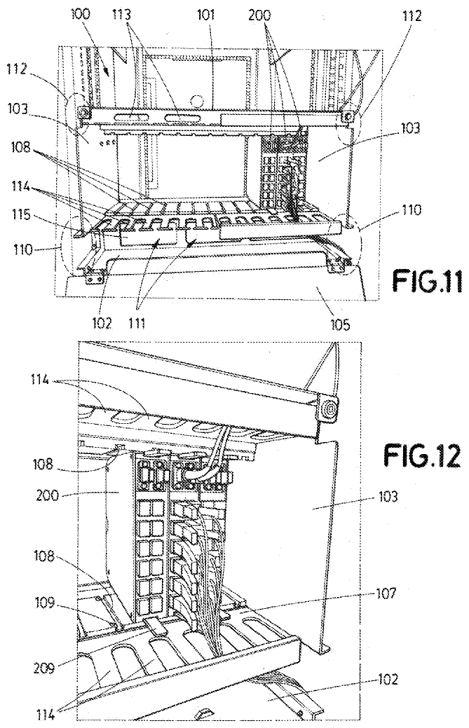

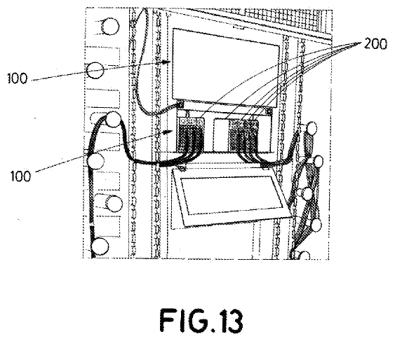

FIGS. 11 and 12 show a particular example where three cassettes (200) are locked inside a chassis (100). FIG. 13 shows two chassis (100) provided inside a cabinet, where the upper chassis (100) is closed and the lower chassis (100) is open.

1. Optical distribution chassis (100) for housing a plurality of optical distribution cassettes (200), the chassis (100) comprising an essentially parallelepipedic enclosure limited by a upper wall (101), a bottom wall (102), lateral walls (103), a back wall (104) and a front door (105), the chassis (100) further comprising coupling means (106) for coupling said chassis (100) inside a networking cabinet, characterized in that:
an intermediate horizontal wall (107) divides the enclosure into an upper enclosure and a lower enclosure, the depth of the intermediate horizontal wall (107) being smaller than the depth of the enclosure such that there is a passage connecting the upper enclosure and the lower enclosure adjacent the front door (105) when closed;
an upper surface of the intermediate horizontal wall (107) and a lower surface of the upper wall (101) each comprise: a plurality of slots (108) oriented in a depth-wise direction for slidably receiving respective mating rails (207) provided in each cassette (200); and a plurality of locking recesses (109) each located adjacent a front end of each slot (108) for receiving respective mating locking protrusions (208) provided in each cassette (200); and
the lower enclosure comprises front lateral openings (110) and back openings (111) for the passage of outgoing cables from the cassettes (200) and the upper enclosure comprises front lateral openings (112) and back openings (113) for the passage of incoming cables to the cassettes (200).

2. Optical distribution chassis (100) according to claim 1, where a front side of the intermediate horizontal wall (107) and the front side of the upper wall (101) each comprise a plurality of fingers (114) separated by respective gaps for the passage of cables, each gap being essentially aligned with one of the plurality of slots (108) for receiving the cassettes (200).

3. Optical distribution chassis (100) according to claim 1, where the front lateral openings (110) of the lower enclosure are openings in a front bottom section of the lateral walls (103) adjacent the front side of the lower enclosure.

4. Optical distribution chassis (100) according to claim 1, further comprising an additional vertical wall (115) separating a front side of the lower enclosure from a back side of the lower enclosure.

5. Optical distribution chassis (100) according to claim 4, where the back openings (111) of the lower enclosure are openings in the additional vertical wall (115).

6. Optical distribution chassis (100) according to claim 1, where the front lateral openings (112) of the upper enclosure are openings in a front upper section of the lateral walls (103).

7. Optical distribution chassis (100) according to claim 1, where the upper wall (101) comprises a front section (101a) and a back section (101b), the back section (101b) being vertically displaced downwards with respect to the front section (101a) for generating an uppermost volume within the upper enclosure, where the back openings (113) of the upper enclosure are openings in a vertical section (101c) of the upper wall (101) connecting the front section (101a) and the back section (101b).

8. Optical distribution chassis (100) according to claim 7, having a height of 6U.

9. Optical distribution chassis (100) according to claim 8, where the height of the upper enclosure is 4.5 U, the height of the uppermost volume within the upper enclosure is 0.5 U, and the height of the lower enclosure is 1.5 U.

10. Optical distribution chassis (100) according to claim 1, where at least one of the front lateral and back openings (110, 111) of the lower enclosure and the front lateral and back openings (112, 113) of the upper enclosure have curved edges for preventing cable damage.

11. Optical distribution cassette (200) for housing a plurality of optical connections, the cassette (200) comprising an essentially paralelepipedic box having a front panel (201), a back panel (202), lateral panels (203), an upper panel (204) and a bottom panel (205), where the front panel (201) comprises a plurality of holes (206) for receiving several connectors, and having a width that is substantially smaller than the height and depth such that a plurality of cassettes (200) can be locked side-by-side inside a chassis (100), characterized in that:
an upper surface of the upper panel (204) and a bottom surface of the bottom panel (205) of the cassette (200) each comprise: a mating rail (207) oriented in the depthwise direction for slidably entering respective slots (108) provided in the chassis (100); and a locking protrusion (208) located adjacent a front end of each rail (207) for entering mating locking recesses (109) provided in the chassis (100).

12. Optical distribution cassette (200) according to claim 11, where each locking protrusion (208) is located at a resilient tongue (209) extending out of the front panel (201) of the cassette (200) , and the locking protrusion (208) is wedge shaped, such that:
full introduction of the cassette (200) in the chassis (100), with the rails (207) provided at the upper panel (204) and bottom panel (205) of the cassette (200) inside the corresponding mating slots (108) provided at the intermediate horizontal wall (107) and the upper wall (101) of the chassis (100), causes the locking protrusion (208) to enter the locking recess (109); and
deflection of the tongue (209) upon application of pressure thereon causes the locking protrusion (208) to exit the locking recess (109) in the chassis (100) for extracting the cassette (200) from the chassis (100).

13. Optical distribution cassette (200) according to claim 11, where the front panel (201) comprises a hole (210) having a pair of slots (211) for receiving a interchangeable plates (212) having differently shaped openings (213) for different types of connectors.

14. Optical distribution cassette (200) according to claim 11, where an inner surface of one of the lateral panels (203) further comprises connection protrusions (215) for the attachment of a splice holder (216) within the cassette (200).

15. Optical distribution cassette (200) according to claim 11, having a height of 4 U.

16. Optical distribution system comprising an optical distribution chassis (100) according to claim 1 and a plurality of optical distribution cassettes (200).
